(19) United States
(12) Patent Application Publication
(10) Pub. No.: US 2006/0292859 A1
(43) Pub. Date: Dec. 28, 2006

(54) Damascene process using dielectic layer containing fluorine and nitrogen

(75) Inventors: Shiu-Ko Jang Jian, Kaohsiung Hsien (TW); Sheng-Wen Chen, Taipei County (TW); Hung-Jui Chang, Changhua County (TW); Ying-Lang Wang, Taichung County (TW)

Correspondence Address: BIRCH STEWART KOLASCH & BIRCH, PO BOX 747, FALLS CHURCH, VA, 22040-0747, US

(73) Assignee: TAIWAN SEMICONDUCTOR MANUFACTURING CO., LTD.

(21) Appl. No.: 11/166,237

(22) Filed: Jun. 27, 2005

(51) Int. Cl. H01L 21/4763

(52) U.S. Cl. 438/623; 438/637; 438/638

(57) ABSTRACT

An improved damascene process for fabricating a semiconductor device. A dielectric layer comprising at least both fluorine and nitrogen is formed overlying a substrate, in which a nitrogen content in the dielectric layer is about 5% to 10%. The dielectric layer is subsequently pattered to form at least one damascene opening therein. A metal layer is formed overlying the dielectric layer and fills the damascene opening. The excess metal layer on the dielectric layer is removed to leave the metal layer in the damascene opening. A semiconductor device with the same damascene structure is also disclosed.

### BACKGROUND

The present invention relates to a method for fabricating a semiconductor device, and particularly to a damascene process for fabricating a semiconductor device, using a dielectric layer containing both fluorine and nitrogen.

Advanced semiconductor processing technologies, such as high-resolution photolithography and anisotropic plasma etching, are dramatically reducing the feature sizes of semiconductor devices, resulting in increased device packing density on semiconductor substrates. In order to achieve this high density for integrated circuits, it has become necessary to use conductive materials with low resistivity (for example, copper) and insulators with low dielectric constants (dielectric constant (k)<4.0), thereby reducing capacitive coupling between adjacent metal lines.

Typically, a damascene method is employed to fabricate semiconductor devices having copper containing materials and low k dielectric materials. Conventional low k materials, such as fluorosilicate glass (FSG) or hydrogen silsesquioxane (HSQ), however, have poor mechanical properties, resulting in damage to low k materials after removal of excess copper by chemical mechanical polishing (CMP). Thus, the performance and reliability of semiconductor devices may be reduced due to damage to low k materials.

U.S. Pat. No. 5,578,530 to Muroyama et al. is a method of forming a semiconductor device having a fluorine-containing silicon nitride layer. The dielectric constant of the fluorine-containing SiN layer can be lowered because the SiN layer thus formed contains fluorine.

U.S. Pat. No. 6,541,397 to Bencher discloses how a low k material can be protected from damage by an overlying amorphous carbon layer.

U.S. Pat. No. 6,541,400 to Tian et al. discloses an improved method for depositing a robust fluorosilicate glass without additional processing. The robust fluorosilicate glass is deposited using specific vapor phase chemicals, such as N₂, SiF₄, SiH₄, and N₂O, improving its chemical, mechanical, and thermal properties.

U.S. Pat. No. 6,777,171 to Xu et al. discloses a fluorine-containing organosilicate layer for a damascene structure. The organosilicate layer incorporated with fluorine may reduce the dielectric constant thereof. Moreover, the fracture strength of the fluorine-containing organosilicate layer may be improved by a plasma treatment.

However, an additional protective layer formed on a low k material layer may complicate the fabrication steps and increase the fabrication cost. Additionally, the low k dielectric layer incorporating an unsuitable fluorine content or nitrogen cannot improve the mechanical properties thereof while maintaining or reducing its dielectric constant.

### SUMMARY

A semiconductor device and a damascene process for fabricating the same are provided. An embodiment of a semiconductor device comprises a dielectric layer and a metal layer. The dielectric layer overlies a substrate, having at least one damascene opening therein, wherein the dielectric layer comprises at least both fluorine and nitrogen, and nitrogen content is about 5% to 10%. The metal layer is disposed in the damascene opening.

An embodiment of a damascene process for fabricating a semiconductor device comprises depositing a dielectric layer comprising at least both fluorine and nitrogen on a substrate, wherein nitrogen content in the dielectric layer is about 5% to 10%. The dielectric layer is patterned to form at least one damascene opening therein. A metal layer is formed overlying the dielectric layer and fills the damascene opening. The excess metal layer overlying the dielectric layer is removed to leave the metal layer in the damascene opening.

### BRIEF DESCRIPTION OF THE DRAWINGS

A damascene process for fabricating a semiconductor device using a dielectric layer containing both fluorine and nitrogen will become more fully understood from the detailed description given hereinbelow and the accompanying drawings, given by way of illustration only and thus not intended to be limitative of the invention.

FIGS. 1A and 1F are cross-sections of an embodiment of a dual damascene process for fabricating a semiconductor device of the invention.

FIG. 2 is a curve diagram showing the relationship between the deposition temperature and the hardness of various dielectric layers.

FIG. 3 is a curve diagram showing the relationship between the deposition temperature and the dielectric constant of various dielectric layers.

FIG. 4 is a curve diagram showing the relationship between the electric field and the leakage current density of various dielectric layers.

### DESCRIPTION

As will be appreciated by persons skilled in the art from the discussion herein, the present invention has wide applicability to many manufacturers, factories and industries. For discussion purposes, the embodiments are made herein to semiconductor foundry manufacturing (i.e., wafer fabrication in an IC foundry). However, the present invention is not limited thereto.

The invention relates to an improved damascene process for fabricating a semiconductor device, using a dielectric layer containing both fluorine and nitrogen to enhance mechanical properties thereof while maintaining a low dielectric constant.

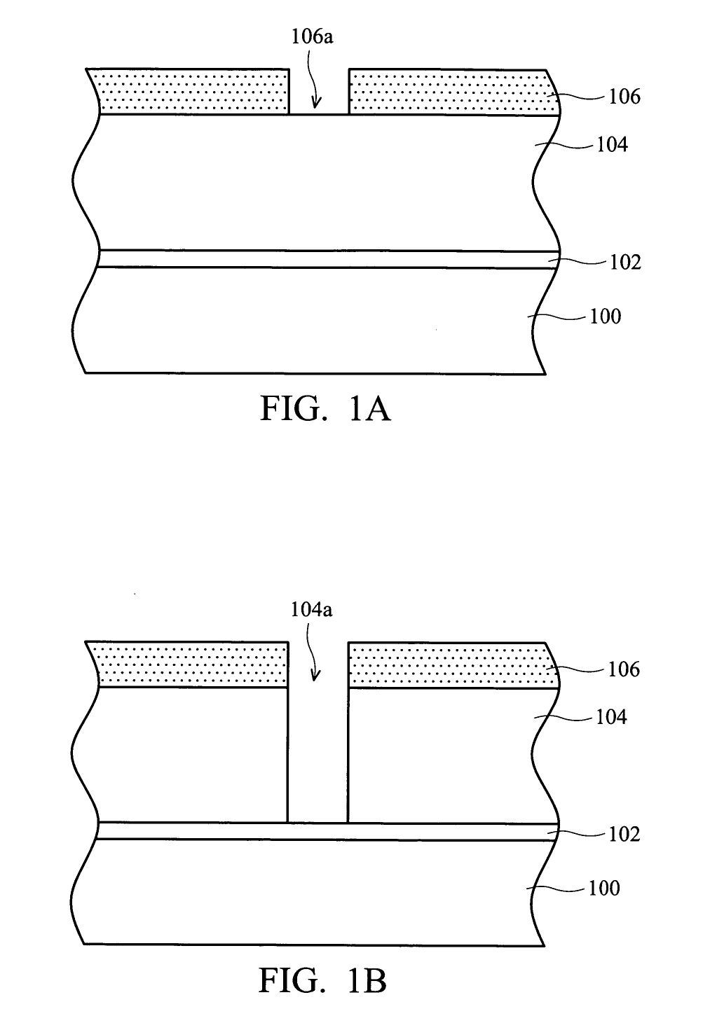

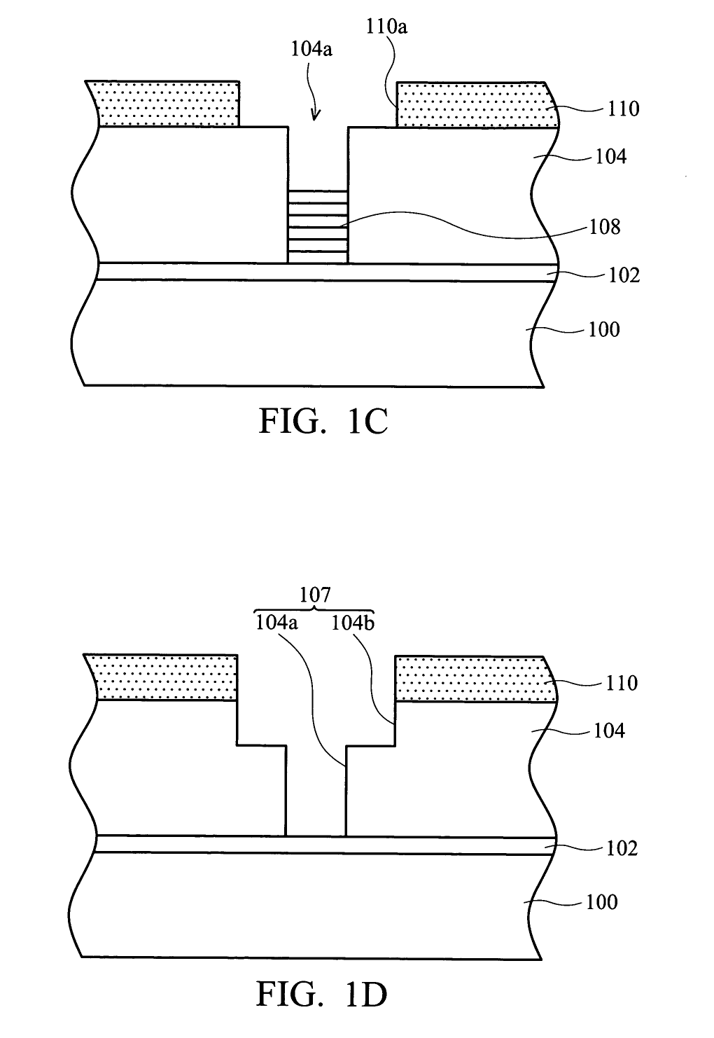

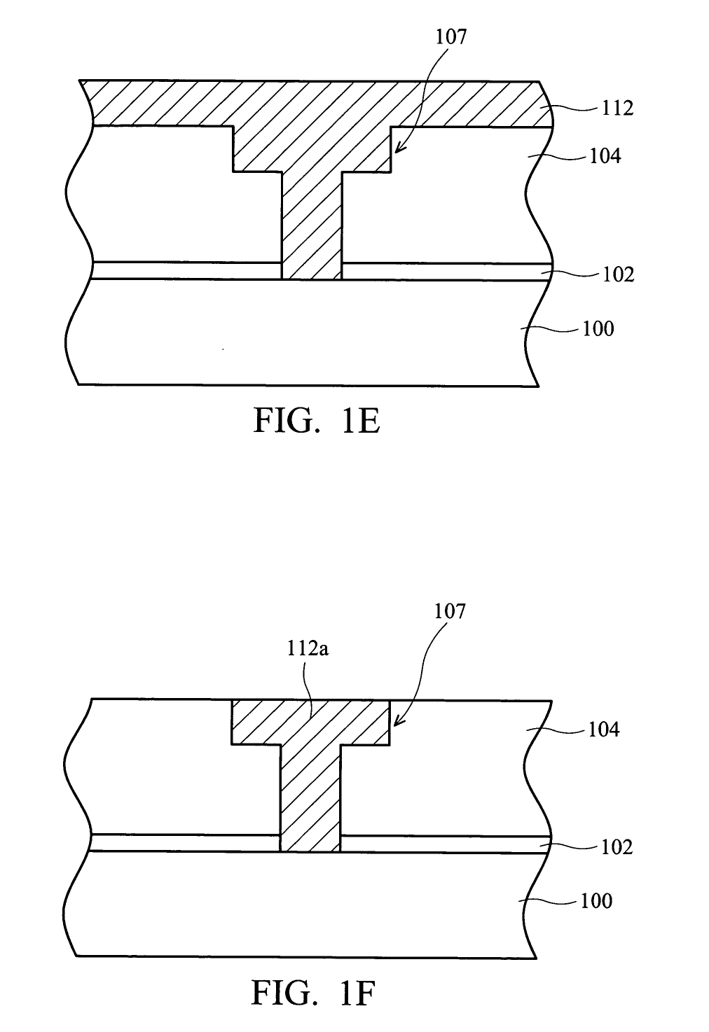

FIG. 1F illustrates an embodiment of a semiconductor device comprising a low dielectric constant material. The semiconductor device comprises a substrate 100, a dielectric layer 104, and a metal layer 112a. The dielectric layer 104, such as an interlayer dielectric (ILD) layer or an intermetal dielectric (IMD) layer, overlies the substrate 100, having at least one damascene opening 107 therein. The damascene opening 107 may comprise a via hole, a trench, or combinations thereof. A diffusion barrier or stop layer 102, such as a silicon nitride layer, is typically disposed between the substrate 100 and the dielectric layer 104. The metal layer 112a, such as a copper layer, is disposed in the damascene opening 107, serving as an interconnect. In general, a thin metal barrier layer (not shown), such as titanium nitride (TiN), is disposed over the inner surface of the damascene opening 107. In this embodiment, the dielectric layer 104 may comprise a low dielectric constant (k) material, such as organosilicate glass (OSG). In particular, the dielectric layer 104 contains at least both fluorine (F) and nitrogen (N) with a content of about 5% to 10%, respectively, contributing superior mechanical properties while maintaining a low dielectric constant.

FIGS. 1A and 1F are cross-sections of an embodiment of a dual damascene process for fabricating a semiconductor device. In FIG. 1A, a substrate 100, such as a silicon substrate or other semiconductor substrate, is provided. The substrate 100 may contain a variety of elements, including, for example, transistors, resistors, and other semiconductor elements as are well known in the art. The substrate 100 may also contain conductive layers. The conductive layer is typically a layer comprising metal, such as copper, commonly used in the semiconductor industry for wiring the discrete semiconductor devices in and on the substrate. In order to simplify the diagram, a flat substrate is depicted.

Next, a stop or diffusion barrier layer 102 is deposited on the substrate 100 to protect the underlying conductive layer (not shown) from damage or contamination during subsequent deposition and etching. The stop layer 102 may comprise silicon nitride and is formed by, for example, plasma enhanced chemical vapor deposition (PECVD) using a process gas mixture such as silane (SiH₄) and ammonia (NH₃)

Next, a dielectric layer 104 is deposited on the stop layer 102, serving as an ILD or IMD layer, by conventional deposition, such as plasma enhanced chemical vapor deposition (PECVD), low pressure CVD (LPCVD), atmospheric pressure CVD (APCVD), high-density plasma CVD (HDPCVD) or other suitable CVD. Generally, the dielectric layer 104 comprises a low k material, such as organosilicate glass (OSG), to achieve low RC time constant (resistance-capacitance). Low k materials, however, have poor mechanical properties, resulting in damage of the ILD or IMD layer during subsequent polishing, as mentioned. In order to improve the mechanical properties of the dielectric layer 104, nitrogen may be doped therein, thereby enhancing the mechanical properties thereof. Note that the k value of the dielectric layer 104 may be increased as the nitrogen content is increased. Thus, if the nitrogen content is excessive, the performance of semiconductor device is decreased because of RC delay. Accordingly, suitable nitrogen content is required. In this embodiment, the nitrogen content is about 5% to 10%. Additionally, in order to reduce the dielectric constant of the nitrogen-containing dielectric layer 104, fluorine may further be doped therein. Note that excess fluorine may result in an unstable dielectric layer because of fluorine precipitation. Accordingly, suitable fluorine content is also required. In this embodiment, the fluorine content is about 5% to 10%.

In this embodiment, the dielectric layer 104 comprising both nitrogen and fluorine may be formed by conventional CVD using a process gas mixture comprising trimethylsilane (SiC₃H₁₀), oxygen (O₂), and nitrogen tri-fluoride (NF₃). The process gas mixture may optionally comprise an inert gas, such as helium (He) or argon (Ar). Moreover, process conditions may include a pressure of about 2 to 4 Torr and a deposition temperature of about 200° C. to 400° C., and 350° C. In particular, the flow ratio of nitrogen tri-fluoride to trimethylsilane is about 0.5:1. In another embodiment, the flow ratio of nitrogen tri-fluoride to trimethylsilane is about 1:1.

After the dielectric layer 104 is formed on the stop layer 102, an anti-reflective layer (not shown) may be optionally deposited overlying the dielectric layer 102. The anti-reflective layer may comprises oxynitride (SiON) formed by CVD using, for example, SiH₄, O₂, and N₂ as a process gas mixture. A masking layer (not shown), such as photoresist, is coated on the dielectric layer 104, and photolithography is subsequently performed on the masking layer to form a masking pattern layer 106 having at least one opening 106a to expose a portion of dielectric layer 104 for damascene structure definition.

As shown in FIG. 1B, conventional etching, such as reactive ion etching (RIE), is performed on the dielectric layer 104 using the masking pattern layer 106 as an etch mask to form an opening 104a therein, serving as a via or contact hole 104a.

After removal of the masking pattern layer 106 by suitable solution or plasma stripping, a fill material layer (not shown), such as a bottom anti-reflection coating (BARC) layer, is formed overlying the dielectric layer 104 and fills the opening 104a. Thereafter, the fill material layer is recessed by, for example, dry etching, to form a sacrificial layer 108 in the lower portion of the opening 104a, as shown in FIG. 1C. Thereafter, a second masking pattern layer 110, such as a photoresist layer, is formed by photolithography, having at least one opening 110a over the opening 104a for damascene structure definition.

As shown in FIG. 1D, the dielectric layer 104 under the opening 110a and the sacrificial layer 108 are etched to form a trench opening 104b over the opening 104a and expose the stop layer 102 in the bottom of the opening 104a. The trench opening 104b and the underlying opening 104a constitute a dual damascene opening 107.

After removal of the masking pattern layer 110, the exposed stop layer 102 in the bottom of the damascene opening 107 is removed by conventional wet or dry etching. Thereafter, a metal layer 112, such as copper, aluminum, or other well known interconnect material, is formed overlying the dielectric layer 104 and fills the damascene opening 107, as shown in FIG. 1E. The metal layer 112 may be applied by techniques such as CVD, sputtering, evaporation, ECD and the like.

Finally, in FIG. 1F, the excess metal layer 112 over the dielectric layer 104 is removed by polishing, such as CMP, to leave a portion of metal layer 112a in the damascene opening 107 to serve as an interconnect and complete the interconnect structure fabrication for the semiconductor device.

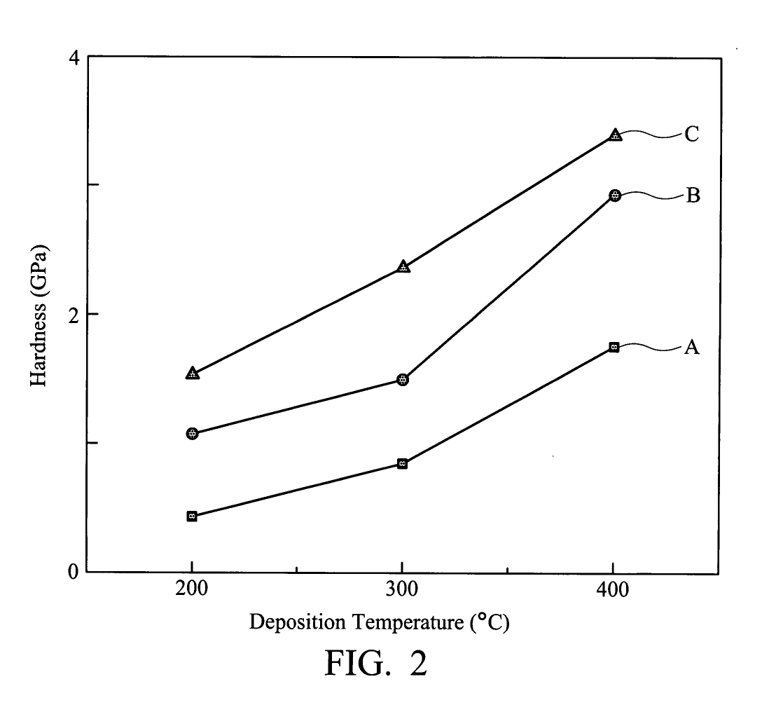

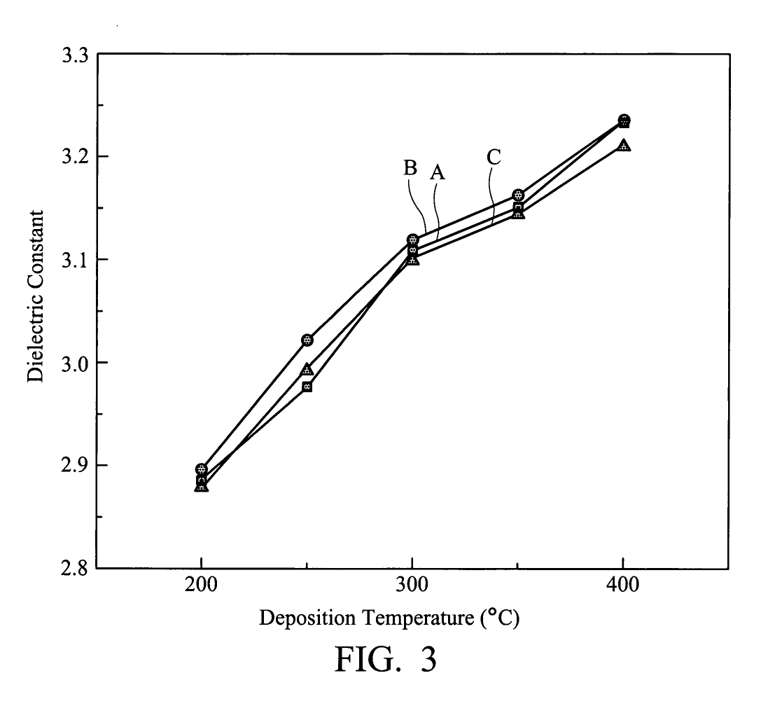

Referring to FIGS. 2 and 3, FIG. 2 is a curve diagram of the relationship between the deposition temperature (° C.) and the hardness (GPa) of various dielectric layers and FIG. 3 a curve diagram of the relationship between the deposition temperature (° C.) and the dielectric constant (k) of various dielectric layers. In FIGS. 2 and 3, curve A indicates an OSG layer without containing nitrogen or fluorine, and curves B and C indicate an OSG layer formed using a process gas mixture comprising trimethylsilane and nitrogen tri-fluoride, wherein the flow ratio of nitrogen tri-fluoride to trimethylsilane are about 0.5:1 and 1:1, respectively. In FIG. 2, the hardness of curve B and that of curve C are higher than that of curve A. That is, the OSG layer comprising nitrogen and fluorine may effectively provide superior mechanical properties. In FIG. 3, the k values of curves A, B, C are similar. That is, the OSG layer comprising nitrogen and fluorine may maintain its k value while enhancing its mechanical properties using nitrogen.

Since the dielectric layer 104 containing a suitable nitrogen content, damage during polishing can be prevented by enhancement of its mechanical properties. Moreover, since the dielectric layer 104 further containing a suitable fluorine content, low k value can be maintained while enhancing mechanical properties using nitrogen.

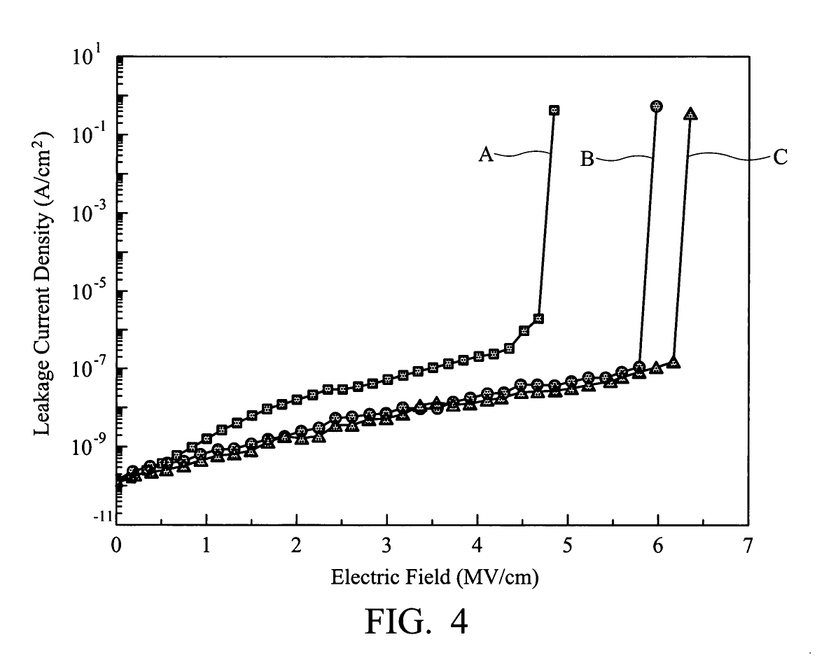

FIG. 4 is a curve diagram of the relationship between the electric field (MV/cm) and the leakage current density (A/cm²) of various dielectric layers. As mentioned, curve A indicates an OSG layer not containing nitrogen or fluorine, and curves B and C indicate an OSG layer formed using a process gas mixture comprising trimethylsilane and nitrogen tri-fluoride, wherein the flow ratio of nitrogen tri-fluoride to trimethylsilane are about 0.5:1 and 1:1, respectively. In FIG. 4, the leakage current density of curves B and C is lower than that of the curve A. That is, the OSG layer comprising nitrogen and fluorine can obtain improved electrical properties.

Accordingly, high performance and reliability of semiconductor devices may be achieved by employing a dielectric layer comprising nitrogen and fluorine as an ILD or IMD layer. Furthermore, according to the invention, formation of an additional protective layer on the low k dielectric layer is not required, thus, the fabrication steps can be simplified and the fabrication cost can be reduced.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A damascene process for fabricating a semiconductor device, comprising:
depositing a dielectric layer comprising at least both fluorine and nitrogen on a substrate, wherein a nitrogen content in the dielectric layer is about 5% to 10%;
patterning the dielectric layer to form at least one damascene opening therein;
forming a metal layer overlying the dielectric layer and filling the damascene opening; and
removing the metal layer overlying the dielectric layer to leave the metal layer in the damascene opening.

2. The process of claim 1, wherein a fluorine content in the dielectric layer is about 5% to 10%.

3. The process of claim 1, wherein the dielectric layer is an organosilicate glass (OSG) layer.

4. The process of claim 1, wherein the dielectric layer is formed using a process gas mixture comprising nitrogen tri-fluoride (NF₃).

5. The process of claim 4, wherein the process gas mixture further comprises trimethylsilane (SiC₃H₁₀) and oxygen.

6. The process of claim 5, wherein the flow ratio of nitrogen tri-fluoride to trimethylsilane is about 0.5:1.

7. The process of claim 5, wherein the flow ratio of nitrogen tri-fluoride to trimethylsilane is about 1:1.

8. The process of claim 1, wherein the dielectric layer is formed at a process pressure of about 2 to 4 Torr.

9. The process of claim 1, wherein the dielectric layer is formed at a process temperature of about 200° C. to 400° C.

10. The process of claim 1, wherein the damascene opening comprises a via hole or a trench.

11. A semiconductor device, comprising:
a substrate;
a dielectric layer overlying the substrate, having at least one damascene opening therein, wherein the dielectric layer comprises at least both fluorine and nitrogen, and a nitrogen content is about 5% to 10%;
and
a metal layer disposed in the damascene opening.

12. The semiconductor device of claim 11, wherein a fluorine content in the dielectric layer is about 5% to 10%.

13. The semiconductor device of claim 11, wherein the dielectric layer is an organosilicate glass (OSG) layer.

14. The semiconductor device of claim 11, wherein the dielectric layer is formed using a process gas mixture comprising nitrogen tri-fluoride (NF₃).

15. The semiconductor device of claim 14, wherein the process gas mixture further comprises trimethylsilane. (SiC₃H₁₀) and oxygen.

16. The semiconductor device of claim 15, wherein the flow ratio of nitrogen tri-fluoride to trimethylsilane is about 0.5:1.

17. The semiconductor device of claim 15, wherein the flow ratio of nitrogen tri-fluoride to trimethylsilane is about 1:1.

18. The semiconductor-device of claim 11, wherein the dielectric layer is formed at a process pressure of about 2 to 4 Torr.

19. The semiconductor device of claim 11, wherein the dielectric layer is formed at a process temperature of about 200° C. to 400° C.

20. The semiconductor device of claim 11, wherein the damascene opening comprises a via hole or a trench.
